(19) United States
(12) Patent Application Publication
(10) Pub. No.: US 2025/0305152 A1
(43) Pub. Date: Oct. 2, 2025

(54) COMPOSITION, ITS USE AND A PROCESS FOR CLEANING SUBSTRATES COMPRISING COBALT AND COPPER

(71) Applicant: BASF SE, Ludwigshafen Am Rhein (DE)

(72) Inventors: Haci Osman GUEVENC, Ludwigshafen am Rhein (DE); Michael LAUTER, Ludwigshafen am Rhein (DE); Andreas KLIPP, Ludwigshafen am Rhein (DE); Sheng-hsuan WEI, Taoyuan (TW); Sinja Verena KLENK, Ludwigshafen am Rhein (DE); Guillaume Michel Jacques GARIVET, Ludwigshafen am Rhein (DE); Lukas MAYR, Ludwigshafen am Rhein (DE); Peter BROEKMANN, Bern (CH); Alena CEDENO LOPEZ, Bern (CH); Mei Chin SHEN, Taoyuan City (TW)

(21) Appl. No.: 18/865,709

(22) PCT Filed: May 26, 2023
(86) PCT No.: PCT/EP23/64197

§ 371 Date: Nov. 14, 2024

(30) Foreign Application Priority Data
May 31, 2022 (EP) 22176555.5

(51) Int. Cl. C23G 1/18; B81C 1/00; C23G 1/20; H01L 21/02

(52) U.S. Cl. CPC C23G 1/18; B81C 1/00849; C23G 1/20; H01L 21/02074; B81C 2201/0126

(57) ABSTRACT

Disclosed herein is an alkaline composition for cleaning a substrate including a structure of copper or copper alloy and a structure including cobalt or cobalt alloy, the composition including:
(a) 0.0001 to 0.2% by weight of a cobalt corrosion inhibitor selected from a surfactant

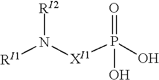

(b) 0.0001 to 0.5% by weight of a copper corrosion inhibitor selected from benzotriazole, 5-chloro benzotriazole, 4-methyl benzotriazole; 5-methyl benzotriazole; tetrahydro benzotriazole; and methyl-benzotriazole-1-yl)-methyl-imino-bis-ethanol;
(c) 0.05 to 1% by weight of a C₂ to C₇ monoamino alkanol; and
(d) a solvent;
   where the solvent consists essentially of water.

The present invention relates to a composition, its use and a process for cleaning substrates comprising a structure of copper or copper alloy and a structure or a barrier or adhesion layer comprising cobalt or cobalt alloy.

### BACKGROUND OF THE INVENTION

The fabrication of electrical devices, in particular, semiconductor integrated circuits (ICs); liquid crystal panels; organic electroluminescent panels; printed circuit boards; micro machines; DNA chips; micro plants and magnetic heads; preferably ICs with LSI (large-scale integration) or VLSI (very-large-scale integration); as well as optical devices, in particular, optical glasses such as photo-masks, lenses and prisms; inorganic electro-conductive films such as indium tin oxide (ITO); optical integrated circuits; optical switching elements; optical waveguides; optical monocrystals such as the end faces of optical fibers and scintillators; solid laser monocrystals; sapphire substrates for blue laser LEDs; semiconductor monocrystals; and glass substrates for magnetic disks; requires high precision methods which involve inter alia surface preparation, pre-plaiting cleaning, post-etch cleaning and/or post-chemical polishing cleaning steps using high-purity cleaning compositions.

Particular care has to be taken in the fabrication of ICs with LSI or VLSI. The semiconductor wafers used for this purpose include a semiconductor substrate such as silicon, into which regions are patterned for the deposition of different materials having electrically insulative, conductive or semiconductive properties.

In order to obtain the correct patterning, excess material used in forming the various layers on the substrates must be removed. Further, to fabricate functional and reliable ICs, it is important to have flat or planar semiconductor wafer surfaces. Thus, it is necessary to clean, remove and/or polish certain surfaces of a semiconductor wafers during the fabrication of the ICs before carrying out the next process steps.

The most processing operations involving wafer substrate surface preparation, deposition, plating, etching and chemical mechanical polishing variously require cleaning operations to ensure that the ICs are free from contaminants that would otherwise deleteriously affect the function of the ICs, or even render them useless for their intended functions.

One particularly grave issue are the residues that are left on the substrates following CMP processing. During for example Cu-CMP, the copper ion concentration can exceed the maximum solubility of the copper-inhibitor complexes. Therefore, the copper-inhibitor complexes can precipitate from solution and can coagulate into a surface residue. Moreover, these residues can stick to the surface of the polishing pad and accumulate to eventually filling the grooves in the polishing pad. Additionally, abrasive particles and chemicals contained in the CMP slurries as well as reaction by-products can be left behind on the wafer surface. Furthermore, the polishing of copper damascene structures containing low-k or ultra low-k dielectric materials such as carbon-doped oxides or organic films can generate carbon-rich particles that settle on to the wafer surface. To make matters worse these low-k or ultra low-k dielectric materials as well as silicon carbide, silicon nitride or silicon oxynitride CMP stop layers are very hydrophobic and hence are difficult to clean with water-based cleaning solutions.

Another residue-producing process common to IC manufacturing involves gasphase plasma etching to transfer the patterns of developed photoresist coatings (for forming vias and trenches) to the underlying layers. which may consist of hardmask, interlevel dielectric, etch-stop layers. The post gasphase plasma etch residues, which may include chemical elements present on and in the substrate and in the plasma gases, are typically deposited on the back end of the line (BEOL) structures and, if not removed, may interfere with the subsequent silicidation and contact formation.

As device nodes shrink below 10 nanometers (nm) in advanced semiconductor manufacturing, new materials are introduced for better device performance and manufacturability. Examples of new materials being considered include layers or features made of cobalt or cobalt alloys such as via contacts, cobalt barrier layers, and the like. In case of cobalt metal is used, other materials may be necessary for example as an adhesion layer. Here for example Ti, TiN or Ta, TaN and combinations of these materials may be used. A conductive copper comprising layer may be deposited on top of a cobalt barrier and form features, such as copper trenches or vias.

Cleaning compositions, such as post etch residue removal (PERR) or post CMP cleaning (PCC), that are compatible with cobalt and copper enable manufacturing processes at smaller and more advanced nodes. In the back end of line (BEOL), copper (Cu) is still used as an interconnect metal line, so a cleaning chemistry formulation that is compatible with copper as well as the new materials is advantageous. There is a continuing need for cleaning compositions with controlled or suppressed etch rate and selectivity for films like Ti, TiN, Ta, TaN, Co, Cu, dielectric layers like Si, SiN, SiO₂, low k or high k materials.

From U.S. Pat. No. 5,770,095 it is known to use BTA and derivatives thereof in compositions for chemical mechanical planarization (CMP) compositions to suppress oxidization or corrosion of copper surfaces in an atmosphere or in a solution capable of eating away copper. US 2017/0158913 A discloses a CMP composition for polishing cobalt or cobalt and copper and/or a cobalt alloy, the composition comprising an amino acid and diazoles, triazoles, tetrazoles or their derivatives as a corrosion inhibitor. US 2018/0371371 A1 and US 2019/002802 A disclose an aqueous post CMP cleaning composition including a polyethylene glycol, an anionic polymer poly(acrylic acid), acrylic acid-maleic acid copolymers, polyaspartic acid, polyglutamic acid, polyvinylphosphonic acid, polyvinylsulfonic acid, poly(styrenesulfonic acid), polycarboxylate ethers, poly-phosphorous acids. and copolymers of the polymers thereof.

CN 106 957 748 A discloses an aqueous circuit board cleaning compositions comprising e.g. 3 wt % lauric acid sarcosine, 0.6 wt % benzotriazole, 5.5 wt %, monoethanolamine, organic solvents like 7.7 wt % of dipropylene glycol butyl ether and 7.7 wt % tripropylene glycol butyl ether, and 61.4 wt % water.

CN 106 833 993 A discloses a water-based cleaning agent comprising 50-70 wt % water, 10-25 wt % glycols, 10-20 wt % propylene glycol, 5-10 wt % alcohol amines, 4-10 w % surfactant, 0.2-1 wt % corrosion inhibitor, 0.5-1.5 wt % defoamer and 0.5-1 wt % stabilizer.

WO 2006/127885 A1 discloses an alkaline aqueous cleaning composition for cleaning post-chemical mechanical polishing (CMP) residue and contaminants from a microelectronic device, as well as a method of cleaning residue and contaminants from a microelectronic device. Specifically claimed compositions comprise e.g. 0.11 wt % dodecylbenzene sulfonic acid, 2 wt % 1,2,4 triazole, 9 wt % monoethanolamine, 3.5 wt % ascorbic acid, and 85.39 w % water. They are to be diluted by 5:1 to 50:1.

US 2003/130146 A1 discloses aqueous compositions used to remove post etch organic and inorganic residue as well polymeric residues and contaminants from semiconductor substrates. The compositions are comprised of a water soluble organic solvent, a sulfonic acid and water.

US 2020/231900 A1 discloses cleaning liquids for semiconductor wafers comprising polyoxyalkylene alkyl ether phosphoric acid and a chelating agent such as tartaric acid, which is used for cleaning after chemical mechanical polishing or post-etch cleaning.

However, if the substrates comprise a metallization based, for example, on cobalt and copper (for example Co-liner integration scheme as described in US2012/0161320) and these surfaces can get in contact with the cleaning solution, it has to be taken care that the cleaning solution is compatible with both metals. This is particularly the case for Cu-PCC and PERR solutions. For PERR the metal structures are open only at the bottom of the vias, etched into the dielectric layer. But for post Cu CMP the upper surface of the metallization is completely exposed to the PCC solution. Because the metals or materials showing metallic conductivity are in galvanic contact (Co-liner integration scheme) and immersed in the PERR or PCC cleaning solution, galvanic corrosion might have to be considered as well. Examples of metals involved may be Ru, Pt, Ir, Pd, Re, Rh, Ti, Ta, Mn, Ni, Al, Cr, V, Mo, Zr, Nb, W, Zr, Cu, their alloys and conductive material like TiN and TaN. Cu might be the fill material.

It was an object of the present invention to provide cleaning compositions for processing substrates useful for fabricating electrical devices, in particular, semiconductor integrated circuits (ICs) that comprise a structure of copper or copper alloy and a structure or a barrier or adhesion layer comprising cobalt or cobalt alloy that shows less corrosion of the cobalt and the copper surface on the substrate.

The cleaning compositions should be particularly well-suited for carrying out the above-mentioned cleaning steps, in particular, the post-CMP cleaning of semiconductor wafers during the fabrication of ICs with LSI or VLSI, in particular via the copper damascene or dual damascene process. The cleaning compositions should remove most efficiently all kinds of residues and contaminants generated during the substrate surface preparation, deposition, plating, etching and CMP to ensure that the substrates, in particular the ICs, are free from residues and contaminants that would otherwise deleteriously affect the functions of the electrical and optical devices, in particular the ICs, or render them even useless for their intended functions. In particular, they should prevent the roughening of the cobalt and copper metallization in damascene structures.

### SUMMARY OF THE INVENTION

It has now been found that the use of specific corrosion inhibitors in combination with monoamino alkanols may significantly reduce the copper and cobalt corrosion.

Therefore, one embodiment of the present invention is an alkaline composition for cleaning a substrate comprising a structure of copper or copper alloy and a structure comprising cobalt or cobalt alloy, the composition comprising:
(a) 0.0001 to 0.2% by weight of a cobalt corrosion inhibitor selected from a surfactant selected from
   (i) a C₁₀ to C₂₀ alkyl sulfonic acid or a C₁₂ to C₂₄ alkylbenzene sulfonic acid,
   (ii) a C₈ to C₁₇ alkyl phosphonic acid or an amino phosphonic acid of formula I1

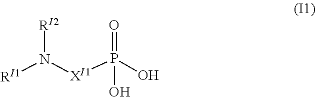

wherein
R^{I1} is C₈ to C₂₀ alkyl,
R^{I2} is selected from H, C₁ to C₆ alkyl, and —X^{I1}—P(O)(OH)₂, and
X^{I1} is selected from C₁ to C₆ alkanediyl,
(iii) a C₁₂ to C₁₈ alkyl carboxylic acid or a sarcosine of formula I2 or cocoyl sarcosine

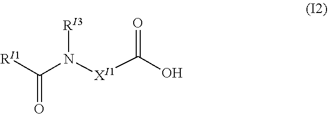

wherein
R^{I1} is C₁₂ to C₂₀ alkyl,
R^{I3} is selected from H, C₁ to C₆ alkyl, and —X^{I1}—C(O)—OH, and
X^{I1} is selected from C₁ to C₆ alkanediyl,
(iv) a C₁₀ to C₂₀ mono or dialkylester of phosphoric acid,
which alkyl groups (i) to (iv) may be interrupted by one or more O or may comprise one or more double bonds,
(v) a salt of (i) to (iv);
(b) 0.0001 to 0.5% by weight of a copper corrosion inhibitor selected from benzotriazole, 5-chloro benzotriazole, 4-methyl benzotriazole; 5-methyl benzotriazole; tetrahydro benzotriazole; and methyl-benzotriazole-1-yl)-methyl-imino-bis-ethanol;
(c) 0.05 to 1% by weight of a C₂ to C₇ monoamino alkanol; and
(d) a solvent;
wherein the solvent consists essentially of water.

Another embodiment of the present invention is a concentrate for preparing a composition as described herein, the concentrate comprising:
(a) 0.01 to 5% by weight of the cobalt corrosion inhibitor;
(b) 0.01 to 1% by weight of the copper corrosion inhibitor;
(c) 1 to 20% by weight of the monoamino alkanol;
(d) 0 to 20% by weight of one or more organic solvents; and
(e) rest water.

Yet another embodiment of the present invention is the use of a composition as described herein for removing
(a) post etch residue (PERR) or post ash residue (PARR), or
(b) chemical mechanical planarization (CMP) residues,
from a substrate comprising (i) a cobalt or cobalt alloy surface and (ii) a copper or copper alloy surface.

Yet another embodiment of the present invention is a process of processing a microelectronic device, the process comprising:
(a) providing a microelectronic substrate that comprises (i) a cobalt or cobalt alloy surface and
   (ii) a copper or copper alloy surface having post etch residues, post ash residues, or chemical mechanical planarization (CMP) residues thereon;
(b) providing a composition according to anyone of claims 1 to 10; and
(c) contacting (i) the cobalt or cobalt alloy surface and (ii) the copper or copper alloy surface with the composition for a time and at a temperature effective to at least partly, preferably completely, remove the post etch residues, post ash residues, or chemical mechanical planarization (CMP) residues from the substrate.

In view of the prior art discussed above, it was surprising and could not be expected by the skilled artisan that the objects underlying the present invention could be solved by the compositions and the methods of the invention.

It was particularly surprising that the specific cobalt inhibitors as described herein and a copper inhibitor selected from a triazole in combination with a C₂ to C₆ monoamino alkanol is associated with a synergistic effect with respect to cobalt and copper corrosion.

The compositions of the invention were most particularly well-suited for carrying out the above-mentioned cleaning steps, in particular, the post-CMP cleaning of semiconductor wafers and the fabrication of ICs with LSI or VLSI, in particular by the copper damascene or dual damascene process.

The compositions of the invention removed most efficiently all kinds of residues and contaminants generated during the substrate surface preparation, deposition, plating, etching and CMP and ensured that the substrates, in particular the ICs, were free from residues and contaminants that would have otherwise deleteriously affected the functions of the electrical and optical devices, in particular the ICs, or would have rendered them even useless for their intended functions. In particular, they prevented the scratching, etching and roughening of the copper metallization in damascene structures.

### DETAILED DESCRIPTION OF THE INVENTION

The compositions of the invention are aqueous alkaline cleaning compositions for processing substrates useful for fabricating electrical and optical devices.

### Definitions

“Aqueous” means that the compositions of the invention contain water. The water content can vary broadly from composition to composition.

“Solvent essentially consisting of water” preferably means that the total amount of any solvents in the composition besides water, particularly the amount of one or more water-miscible organic solvent, is about 1% by weight or less, more preferably about 0.5% by weight or less, most preferably about 0.3% by weight or less, based on the total weight of the composition.

“Alkaline” means that the compositions of the invention have a pH in the range of from 7.5 to 14, preferably from 9 to 13 and, more preferably from 9.5 to 12.5, even more preferably from 10 to 12, most preferably from 10.5 to 11.5.

“Chemical bond” means that the respective moiety is not present but that the adjacent moieties are bridged so as to form a direct chemical bond between these adjacent moieties. By way of example, if in a molecule A-B-C the moiety B is a chemical bond then the adjacent moieties A and C together form a group A-C.

“Copper inhibitor” means a compound that inhibits static removal of copper from the substrate by etching. “Cobalt inhibitor” means a compound that inhibits static removal of cobalt from the substrate by etching.

The term “Cₓ” means that the respective group comprises x numbers of C atoms. The term “Cₓ to C_{y} alkyl” means alkyl with a number x to y of carbon atoms and, unless explicitly specified, includes unsubstituted linear, branched and cyclic alkyl. In the context of the alkyl carboxylic acid corrosion inhibitors, Cₓ to C_{y} alkyl means the alkyl group without the “C” atom of the carboxylic functional group.

As used herein, “alkanediyl” refers to a diradical of linear, branched or cyclic alkanes or a combination thereof.

“Structure” herein means a structure made of the respective material, such as but not limited a structured or continuous layer of the material.

All percent, ppm or comparable values refer to the weight with respect to the total weight of the respective composition except where otherwise indicated. The term wt % means % by weight.

All cited documents are incorporated herein by reference.

### Cobalt Corrosion Inhibitor

The cleaning composition according to the invention comprises an anionic type surfactant as a cobalt inhibitor.

In a first embodiment the cobalt corrosion inhibitor is a C₁₀ to C₂₀ alkyl sulfonic acid or a C₁₂ to C₂₄ alkylbenzene sulfonic acid. Without limitation, examples of C₁₀ to C₂₀ alkyl sulfonic acids are 1-dodecanesulfonic acid, 1-tridecanesulfonic acid, 1-tetradecanesulfonic acid, 1-pentadeacensulfonic acid, 1-hexadecanesulfonic acid, 1-heptadecanesulfonic acid, 1-octadecanesulfonic acid, 1-nonadecanesulfonic acid, and mixtures thereof. Without limitation, examples of C₁₂ to C₂₄ alkylbenzene sulfonic acid are dodecylbenzenesulfonic acid, 4-tridecylbenzenesulfonic acid, 4-tetradecylbenzene sulfonic acid, 4-pentadecylbenzenesulfonic acid, 4-hexadecylbenzensulfonic acid, and mixtures thereof.

In a second embodiment the cobalt corrosion inhibitor is a C₈ to C₁₇ alkyl phosphonic acid or an amino phosphonic acid of formula I1

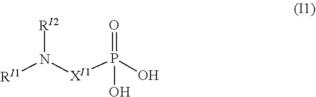

wherein
R^{I1} is C₈ to C₂₀ alkyl, preferably C₁₀ to C₁₈ alkyl;
R^{I2} is selected from H, C₁ to C alkyl, and —X^{I1}—P(O)(OH)₂, preferably selected from H, C₁ to C₄ alkyl, and —X¹—P(O)(OH)₂, most preferably —X^{I1}—P(O)(OH)₂; and
X^{I1} is selected from C₁ to C₆ alkanediyl, preferably selected from C₁ to C₄ alkanediyl, most preferably selected from methanediyl and ethanediyl.

A particularly preferred alkyl phosphonic acid type cobalt corrosion inhibitor is octadecylphosphonic acid. Particularly preferred cobalt corrosion inhibitors of formula I1 are N-coco-alkyl derivatives of iminobis(methylene)bisphosphonic acid.

In a third embodiment the cobalt corrosion inhibitor is a C₁₂ to C₁₈ alkyl carboxylic acid, a sarcosine of formula I2, or cocoyl sarcosine (a mixture of C₇- to C₁₇ alkyl sarcosines)

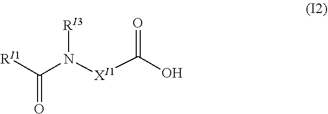

wherein
R^{I1} is C₁₂ to C₂₀ alkyl,
R^{I3} is selected from H, C₁ to C₆ alkyl, and —X^{I1}—C(O)—OH, preferably selected from H and C₁ to C₄ alkyl, most preferably methyl, ethyl or propyl, and
X^{I1} is selected from C₁ to C₆ alkanediyl, preferably selected from C₁ to C₄ alkyl, most preferably selected from methanediyl, ethanediyl and propanediyl.

The compounds of formula I2 may be used as a single compound or as a mixture of compounds. Preferred C₁₂ to C₁₈ alkyl carboxylic acid corrosion inhibitors are myristic acid, palmitic acid, stearic acid, palmitoleic acid, elaidic acid, linoleic acid, and mixtures thereof. Preferred corrosion inhibitor of formula I1 are N-Cocoyl sarcosine (a mixture of C₇ to C₁₇ alkyl sarcosines) and N-Oleyl sarcosine (a C₁₂ alkyl sacosine).

In a fourth embodiment the cobalt inhibitor is a C₆ to C₂₀ mono or dialkylester of phosphoric acid, preferably a C₆-C₁₀ mono- or dialkylester.

In all embodiments (i) to (iv) the alkyl groups may optionally be interrupted by one or more O, preferably one or two O. Most preferably the alkyl groups are not interrupted by any O atoms.

In all embodiments (i) to (iv) the alkyl groups may optionally comprise one or more double bonds, preferably one or two double bonds. Most preferably the alkyl groups do not comprise any double bonds.

Alternatively, the respective salt of the compounds (i) to (iv) may be used. The counter-ion may be any cation that does not interfere with the substrate.

The cobalt corrosion inhibitor may be used in an amount of from about 0.0001 to about 0.2% by weight, preferably of from about 0.001 to about 0.15% by weight, more preferably of from about 0.002 to about 0.1% by weight, most preferably of from about 0.005 to about 0.05% by weight, based on the total weight of the composition.

### Copper Corrosion Inhibitor

The cleaning composition according to the invention comprises a copper corrosion inhibitor.

The copper corrosion inhibitors are selected from benzotriazole, 5-chloro benzotriazole, 4-methyl benzotriazole; 5-methyl benzotriazole; tetrahydro benzotriazole; and methyl-benzotriazole-1-yl)-methyl-imino-bis-ethanol.

The copper corrosion inhibitor may be used in an amount of from about 0.0001 to about 0.5% by weight, preferably of from about 0.001 to about 0.3% by weight, more preferably of from about 0.002 to about 0.1% by weight, most preferably of from about 0.002 to about 0.05% by weight, based on the total weight of the composition.

Compositions according to the invention comprising the etchant in the here defined preferred total amounts have shown a superior suppression of the static etch rate of cobalt and copper.

### Monoamino Alkanol

The composition according to the invention further comprises a C₂ to C₇ monoamino alkanol as pH adjustor to adjust an alkaline pH in a dominating aqueous solution. The pH adjustor should not corrode the metal, for example cobalt, significantly or leave any residues on the surface post treatment. This can be assessed by the static etching rate with subsequent visual inspection of the processed metal coated wafer coupon. Examples of organic amines are primary, secondary or tertiary amines.

The mono-amine comprises one or more hydroxy groups and optionally one or more ether groups. Examples are 2-(2-Aminoethoxy)ethanol (Diglycolamine), Diethanolamine, Monoethanolamine, Triethanolamine, Diisopropanolamine, 2-Amino-1-propanol, Triisopropanolamine, 3-Dimethylaminopropane-1-ol, Butyldiethanolamine, Dibutylethanolamine, Ethylethanolamine, Dimethylethanolamine, N-Methyl-diethanolamine, Methyldiisopropanolamine, N,N-Dimethylethanolamin, N,N-Dimethylisopropanolamine, N-Methylethanolamine, 3-Amino-1-propanol, 4-(2-Hydroxyethyl)morpholine, 5-Amino-1-pentanol, 2-[2-(Dimethylamino)ethoxy]ethanol, 2-dimethylamino-2-methyl-1-propanol, 2-Methylamino-2-methyl-1-propanol, 1-Amino-2-propanol (Alaninol), 2-amino-1-methyl propanol (AMP), 4-amino-1-butanol, 3-Amino-1,2-propanediol, Diisopropanolamine, 2-Methoxy-ethylamine, and combinations thereof.

More preferred is a primary C₃ to C₆ monoamino alkanol, such as but not limited to 2-Amino-1-propanol, 3-Amino-1-propanol, 1-Amino-2-propanol, 2-amino-1-methyl propanol (AMP), 2-Methyl-aminoethanol, 3-Amino-1,2-propanediol

In a preferred embodiment the C₃ to C monoamino alkanol is a compound of formula A1

H₂N—X^{A}—OH (A1)
wherein X^{A} is selected from a linear or branched C₃ to C₅, particularly a C₃ to C₄ alkanediyl.

In a particularly preferred embodiment the C₃ to C₆ monoamino alkanol is selected from 2-amino-ethan-1-ol, 2-amino-propan-1-ol, 3-amino-propan-1-ol, 3-amino-propan-2-ol, 2-amino-1-methyl-propan-1-ol, 3-amino-1-methyl-propan-1-ol, 2-amino-2-methyl-propan-1-ol; 2-amino-butan-1-ol, 3-amino-butan-1-ol, 4-amino-butan-1-ol, 2-amino-3-methyl-butan-1-ol, 4-amino-2-methyl-butan-1-ol, 3-amino-1-methyl-butan-1-ol.

The C₃ to C₆ monoamino alkanol may generally be used in amounts of from about 0.04 to about 1% by weight, preferably 0.05 to 0.8% by weight, even more preferably from 0.8 to 0.5% by weight, most preferably from 0.1 to 0.3% by weight.

### Solubilizers

In some embodiments, particularly for post etch residue removal, the cleaning composition may optionally comprise one or more water-miscible organic solvents different from any component defined above, particularly different from the monoamino alkanol, particularly for post etch residue removal, in an amount of about 1% by weight or less.

Such water-miscible organic solvents may preferably be selected from the group consisting of tetrahydrofuran (THF), N-methylpyrrolidone (NMP), di-methyl formamide (DMF), dimethyl sulfoxide (DMSO), ethanol, isopropanol (IPA), butyldiglycol, butylglycol, sulfolane (2,3,4,5-tetrahydrothiophene-1,1-dioxide), 1,3-dioxolan, propylene glycol; ethylene glycol, diethylene glycol, glycerol, 1,4-dioxane, gamma-butyrolactone, acetonitrile and mixtures thereof; more preferably selected from the group consisting of THF, NMP, DMF, DMSO, sulfolane, 1,3-dioxolan, propylene glycol, diethylene glycol, ethylene glycole, glycerol, gamma butyrolactone and mixtures thereof. Most preferably the water-miscible organic solvent may be selected from from the group consisting of THF, DMSO, IPA, propylene glycol, diethylene glycol, ethylene glycole, glycerol, gamma butyrolactone and mixtures thereof.

The term “water-miscible organic solvent” in the context of the present invention preferably means that an organic solvent fulfilling this requirement is miscible with water at least in a 1:1 (w/w) ratio at 20° C. and ambient pressure. Preferably the, or at least one water-miscible organic solvent is DMSO, ethylene glycol, gamma butyrolactone, sulfolane, IPA or propylene glycol. Particularly, preferred post CMP cleaning compositions are compositions according to the present invention which do not comprise one or more water-miscible organic solvents.

In individual cases, a composition according to the invention as defined herein (or a composition according to the invention as described above or below as being preferred) is preferred wherein the total amount of the one or more water-miscible organic solvents, (i.e. the solvent component) present in an amount of from about 0.01 to about 1% by weight, preferably of from about 0.1 to about 1% by weight, more preferably of from about 0.2 to about 1% by weight, even more preferably of from about 0.1 to about 0.5% by weight, and even more preferably of from about 0.3 to about 0.5% by weight or from about 0.03 to about 0.3% by weight, based on the total weight of the composition.

### Dispersing Agents

The composition may also further comprise one or more dispersing agent for dispersing particulate organic, metal organic or inorganic residues. A dispersing agent is a compound that can stabilize a particle in a solvent (water) sterically, electro-sterically or electrostatically. The dispersing agent can be a surfactant or a polymer or a mixture thereof. The dispersing agent must be soluble in the solvent system at the pH adjusted. This can be evaluated by turbidity measurement, carried out preferred at the process temperature the formulation is commercially used. For post CMP cleaning this is usually room temperature. If the formulation comprises a surfactant as dispersing agent, it can be a non-ionic, a zwitter-ionic or a cationic surfactant. Among the surfactants non-ionic surfactants are preferred.

If the formulation comprises a polymer as dispersing agent, it can be an anionic, a zwitterionic, a non-ionic or a cationic polymer. Among the polymers anionic and non-ionic polymers are preferred. These polymers can be homo-polymers or co-polymers from anionic or non-ionic monomers.

Monomers can be ethylene oxide, propylene oxide, styrene, vinyl pyrrolidone, acrylamide, amino acids, carbon hydrates, vinyl alcohol, acrylic acid, malonic acid, methacrylic acid, vinylsulfonic acid, vinylphosphonic acid, formaldehyde, phenolsulfonic acid, naphthalene sulfonic acid

Preferred polymers are polyacrylic acid, polymalonic acid, acrylic acid malonic acid copolymer, acrylic acid styrene copolymer, acrylic acid methacrylic acid copolymer, polyvinylpyrrolidone, polyethylenoxide, ethyleneoxide proypleneoxide copolymer, naphthalenesulfonic acid formaldehyde condensate, phenolsulfonic acid formaldehyde condensate and naphthalenesulfonic acid phenolsulfonic acid formaldehyde mixed condensate.

The mass averaged molar mass MW of the polymer is below 500 000 g/mol, preferrably below 100 000 g/mol, even more preferrably below 10 000 g/mol.

Parts of the dispersing agent for example adsorb on the surface of a particle to be dispersed. Another part of the dispersing agent for example reaches from the particle into the solution. Literature on the structure of adsorbed polymers is well known in the arts and can be found e.g. in Lipatov and Sergeeva, Adsorption of Polymers, 1974. The part of the dispersing agent in the solvent supports that the particles can be rinsed from the surface of a substrate to be cleaned. The improved interaction with the solvent will also increase the barrier between two particles or particle and substrate surface to make sure that agglomeration or redeposition will not happen.

The chemical nature of the solvated part and the part adsorbed onto the particle surface can be the same or different. Analogue dispersing mechanisms and dispersing agents are well known in the arts and are described for example in T. F. Tadros, Applied Surfactants—Principles and Application, first edition from 2005, chapter 7.

### Complexing Agents

The cleaning composition, particularly the post CMP cleaning compositions, may optionally comprise one or more complexing agents.

Complexing agents are well known in the arts.

In general a complexing agent in a liquid medium is able to dissolve metal salts or to prevent dissolved metal ions from forming insoluble precipitates by forming a well soluble complex with the metal ion. The complexing agent is a non-polymeric molecule that comprises at least one functional acidic group that can form a negatively charged group when it is deprotonated. This functional group can be a carboxylic acid, a sulfonic acid, or a phosphonic acid group. The complexing agent may further comprise one or more N-donor, like amine or pyridine type N, or phenol-type OH groups for complexing metal ions. The complexing agent may comprise further functional groups like hydroxy or chloro and the like.

Examples of complexing agents are carboxylic acids such as but not limited to formic acid, acetic acid, propionic acid, or hydroxycarboxylic acids such as but not limited to glycolic acid, lactic acid, glucoronic acid and the like. Further examples are polycarboxylic acids such as but not limited to malonic acid, succinic acid, glutaric acid, tartronic acid, malic acid, tartaric acid, glucaric acid, citric acid and the like. Further examples are amino carboxylic acids such as but not limited to glycine, alanine, serine, proline, valine, glutamic acid, aspartic acid, imino-di-succinic acid, 1,2-cyclohexylenedinitrilotetraacetic acid, ethylenediaminetetra-acetic acid or nitrilo-triacetic acid and the like. Further examples are pyridine carboxylic acids and derivatives such as but not limited to picolinic acid or dipiconlinic acid and the like. Further examples are phenol-carboxylic acid derivatives such as but not limited to salicylic acid and the like. Further examples are sulfonic acids such as but not limited to methane-sulfonic acid and the like. Further examples are amino-sulfonic acids such as but not limited to for example amino-ethanesulfonic acid (taurine), cysteic acid and the like. Further examples are phenol sulfonic acid derivatives such as but not limited to sulfosalicylic acids and the like. Further examples are phosphonic acids like methylphosphonic acid, phosphonobutane-tricarboxylic acid (PBTC) and the like. Further examples are polyphophonic acids such as but not limited to etidronic acid and the like. Further examples are amino phosphonic acids such as but not limited to amino-trimethylenphosphonic acid (ATMP) or diethylene-triamine-penta(methylenephosphonic acid) (DTMP), ethylenediaminetetra(methylenephosphonic acid) (EDTMP) and the like. Mixtures of the above complexing agents may also be used.

Preferred complexing agents are C₂ to C₆ polycarboxylic acids with optionally one or more additional functional hydroxy groups. Particularly preferred complexing agents are oxalic acid, malonic acid, succinic acid, glutaric acid, adipic acid, tartronic acid, malic acid, citric acid, and tartaric acid.

More preferred complexing agents are C₂ to C₆ hydroxy-polycarboxylic acids. Particularly preferred complexing agents are tartronic acid, malic acid, citric acid, and tartaric acid.

Most preferred complexing agent is citric acid.

Preferably the amount of the one or more complexing agents present is of from about 0.001 to about 0.1% by weight, preferably of from about 0.02 to about 1% by weight, more preferably of from about 0.05 to about 0.8% by weight, based on the total weight of the composition.

### Reducing Agent

From former process steps, e.g. CMP or etching steps, residues of oxidizers like H₂O₂, persulfate or periodate might be present and may lead to corrosion of small metal features on the wafer during the subsequent cleaning step. To prevent this, reducing agents that can be oxidized by oxidizers like H₂O₂, persulfate or periodate may be added. Examples of such reducing agents are organic compounds comprising at least one primary or secondary hydroxy group. A preferred type of reducing agents are saturated organic compounds comprising at least four hydroxy groups.

A more preferred type of reducing agents are saturated organic compounds comprising at least four alcoholic hydroxy groups, where one of these hydroxy groups is a primary hydroxy group. Preferred reducing agents are pentaerythrite, tetrahydroxybutane, pentahydroxypentane, hexahydroxyhexane 1,4-sorbitan and the like. The compound may form an acetal compound for example with a carbon hydrate, like isomalt, or be a free molecule, like mannitol. A more preferred type of reducing agents are sugar alcohols comprising at least four hydroxy groups. Examples of such sugar alcohols are sorbitol, arabitol, arabinitol, isomalt, mannitol, threitol, erythritol, xylitol or lactitol. The compound may form an acetal compound for example with a carbon hydrate, like isomalt, or be a free molecule, like mannitol.

A particularly preferred reducing agent is sorbitol.

### Oxygen Scavenger

Ambient oxygen dissolved in the solvent may already be able to damage small metal patterns on a substrate. To prevent this, oxygen scavengers that can be oxidized by oxidizers like O₂ may be added.

Oxygen scavengers are unsaturated organic compounds comprising at least one C—C double bond. This double bond can be isolated or part of a conjugated or aromatic system. A preferred type of oxygen scavengers are furanon and its derivatives, like for example 2-furanon, 3-methyl-2-furanon, 4-hydroxy-2,5-dimethyl-3-furanon, 5-hydroxymethyl-2-furanon, 5-ethyl-3-hydroxy-4-methyl-2-furanon, ascorbic acid or erythorbic acid. More preferred are furanon derivatives comprising at least two OH-groups in the furanon-ring like ascorbic acid or erythorbic acid. Particularly preferred is ascorbic acid.

Another preferred type of oxygen scavengers are phenol derivatives. Examples are Tyrosin, dihydroxybenzene, its isomers hydrochinon, brenzcatechin and resorcin and derivatives like 4-methoxyphenol (MeHQ), trihydroxybenzene, its isomers like pyrogallol and phloroglucine and derivatives like gallic acid or tannin type compounds, tetrahydroxybenzene, its isomers and derivatives.

### Composition

The pH of the cleaning composition is from 7.5 to 12, preferably from 8 to 11.5, even more preferably from 9 to 11.4, most preferably from 9.6 to 11.2.

The solvent consists essentially of water.

In a preferred embodiment the composition is free of any organic solvents solvents besides water (except of those that are monoalkanolamines according to the invention), particularly free of any alkylene glycols, polyalkylene glycols, ethers or polyethers, DMSO or NMP.

In another preferred embodiment the composition comprises a solvent as solubilizer in an amount of 1% by weight or less as described above.

Preferably the composition is essentially free of any particles, particularly silica particles. Essentially free here means that the composition does not comprise any amount of particles that influences the cleaning functionality of the composition. Preferably the particle content is below 10 ppm, more preferably below 1 ppm, most preferably below the detection limit. In a preferred embodiment the composition is filtered before use.

Preferably the composition is essentially free of any oxidizers, particularly any peroxides. Essentially free here means that the composition does not comprise any amount of actively added oxidizers that increase the copper or cobalt corrosion, but specifically excluding ambient oxygen (O₂) dissolved in the composition. Preferably the oxidizer content (except O₂) in the cleaning composition is below 10 ppm, more preferably below 1 ppm. Most preferably the content of any oxidizer (except O₂) is below the detection limit.

A post CMP composition according to the invention as defined herein is specifically preferred wherein the composition consists of
(a) 0.0001 to 0.2% by weight of a cobalt inhibitor selected from an anionic surfactant comprising (A) (i) a sulfonic acid or (ii) a phosphonic acid or (iii) a carboxylic acid, (iv) a phosphoric acid functional group, or (v) a salt thereof; and (B) a C₁₀ to C₃₀ alkyl group, which alkyl group may be interrupted by one or more O;
(b) 0.0001 to 0.5% by weight of copper inhibitor selected from benzotriazole, 5-chloro benzotriazole, 4-methyl benzotriazole; 5-methyl benzotriazole; tetrahydro benzotriazole; and methyl-benzotriazole-1-yl)-methyl-imino-bis-ethanol;
(c) 0.05 to 1% by weight of a C₂ to C₆ monoamino alkanol;
(d) water;
as defined herein and to be defined based on the examples; all based on the total weight of the composition, wherein the pH of the composition is of from about 7.5 to about 12, preferably of from about 9 to about 11.5, and wherein the % amounts of the components add to 100% by weight in each case. The concentrations of the components (a) to (d) may be varied within the preferred ranges described above.

A post CMP composition according to the invention as defined herein is specifically preferred wherein the composition consists of
(a) 0.0001 to 0.2% by weight of a cobalt inhibitor selected from an anionic surfactant comprising (A) (i) a sulfonic acid or (ii) a phosphonic acid or (iii) a carboxylic acid, (iv) a phosphoric acid functional group, or (v) a salt thereof; and (B) a C₁₀ to C₃₀ alkyl group, which alkyl group may be interrupted by one or more O;
(b) 0.0001 to 0.5% by weight of copper inhibitor selected from benzotriazole, 5-chloro benzotriazole, 4-methyl benzotriazole; 5-methyl benzotriazole; tetrahydro benzotriazole; and methyl-benzotriazole-1-yl)-methyl-imino-bis-ethanol;
(c) 0.05 to 1% by weight of a C₂ to C₆ monoamino alkanol;
(d) water;
(e) 0 to 0.5% by weight of a water miscible organic solvent;
as defined herein and to be defined based on the examples; all based on the total weight of the composition, wherein the pH of the composition is of from about 7.5 to about 12, preferably of from about 9 to about 11.5, and wherein the % amounts of the components add to 100% by weight in each case. The concentrations of the components (a) to (e) may be varied within the preferred ranges described above.

A post-etch residue removal composition according to the invention as defined herein is specifically preferred wherein the composition consists of
(a) 0.0001 to 0.2% by weight of a cobalt inhibitor selected from an anionic surfactant comprising (A) (i) a sulfonic acid or (ii) a phosphonic acid or (iii) a carboxylic acid, (iv) a phosphoric acid functional group, or (v) a salt thereof; and (B) a C₁₀ to C₃₀ alkyl group, which alkyl group may be interrupted by one or more O;
(b) 0.0001 to 0.5% by weight of copper inhibitor selected from benzotriazole, 5-chloro benzotriazole, 4-methyl benzotriazole; 5-methyl benzotriazole; tetrahydro benzotriazole; and methyl-benzotriazole-1-yl)-methyl-imino-bis-ethanol;
(c) 0.05 to 1% by weight of a C₂ to C₆ monoamino alkanol;
(d) water;
(e) 0.01 to 1% by weight of a water miscible organic solvent;
as defined herein and to be defined based on the examples; all based on the total weight of the composition, wherein the pH of the composition is of from about 7.5 to about 12, preferably of from about 9 to about 11.5, and wherein the % amounts of the components add to 100% by weight in each case. The concentrations of the components (a) to (e) may be varied within the preferred ranges described above.

The compositions of the invention may be prepared by customary and standard mixing processes and mixing apparatuses such as agitated vessels, in-line dissolvers, high shear impellers, ultrasonic mixers, homogenizer nozzles or counterflow mixers, can be used for carrying out the mixing of the components of the compositions in the desired amounts.

It will be appreciated that it is common practice to make concentrated forms of the compositions to be diluted prior to use. For example, the compositions may be manufactured in a more concentrated form and thereafter diluted with water, at least one oxidizing agent, or other components at the manufacturer, before use, and/or during use. Dilution ratios may be in a range from about 0.1 parts diluent to 1 parts composition concentrate to about 100 parts diluent to 1 part composition concentrate.

It may particularly be prepared by diluting a concentrate comprising:
(a) 0.01 to 5% by weight of the cobalt corrosion inhibitor;
(b) 0.01 to 1% by weight of the copper corrosion inhibitor;
(c) 1 to 20% by weight of the monoamino alkanol;
(d) 0 to 20% by weight of one or more organic solvents; and
(e) rest water
with water, an organic solvent, or a combination thereof. Preferred dilution factors (by volume) are from about 10 to about 100, preferably from about 20 to about 80, most preferably from about 25 to about 60.

### Application

The compositions of the invention are excellently suited for the methods of the invention. The main purpose of the methods of the invention however is the processing of substrates useful for fabricating electrical devices, in particular, semiconductor integrated circuits (ICs), liquid crystal panels; organic electroluminescent panels; printed circuit boards; micro machines; DNA chips; micro plants and magnetic heads; more preferably ICs with LSI (large-scale integration) or VLSI (very-large-scale integration); as well as optical devices, in particular, optical glasses such as photo-masks, lenses and prisms; inorganic electro-conductive films such as indium tin oxide (ITO); optical integrated circuits; optical switching elements; optical waveguides; optical monocrystals such as the end faces of optical fibers and scintillators; solid laser monocrystals; sapphire substrates for blue laser LEDs; semiconductor monocrystals; and glass substrates for magnetic disks.

Preferably, the methods of the invention involve surface preparation, pre-plaiting cleaning, post-etch cleaning or post-CMP cleaning steps, in particular post-etch or post-CMP cleaning steps.

The cleaning compositions are particularly useful for
(a) post etch residue (PERR) or post ash residue (PARR), or
(b) chemical mechanical planarization (CMP) residues, from a substrate comprising (i) a cobalt or cobalt alloy surface and (ii) a copper or copper alloy surface.

The methods of the invention are particularly well-suited for the processing of substrates useful for fabricating ICs with LSI or VLSI, in particular in the back end of the line (BEOL) processing.

The methods of the invention are most particularly well-suited for the post-CMP cleaning of semiconductor wafers in the fabrication of ICs with LSI or VLSI, in particular by the copper damascene or dual damascene process.

Accordingly, one embodiment relates to a kit including, in one or more containers, one or more components adapted to form the compositions described herein. Preferably, one container comprises the at least one oxidizing agent and a second container comprises the remaining components, e.g., at least one etchant, at least selectivity enhancer, water, and optionally other components described herein, for combining at the fab or the point of use.

In the use of the compositions described herein, the composition typically is contacted with the device structure for a sufficient time of from about 25 seconds to about 200 minutes, preferably about 5 minutes to about 60 minutes, at temperature in a range of from about 10° C. to about 80° C., preferably about 20° C. to about 60° C. Such contacting times and temperatures are illustrative, and any other suitable time and temperature conditions may be employed that are efficacious to achieve the required removal selectivity.

Following the achievement of the desired cleaning action, the composition can be readily removed from the microelectronic device to which it has previously been applied, e.g., by rinse, wash, or other removal step(s), as may be desired and efficacious in a given end use application of the compositions of the present invention. For example, the device may be rinsed with a rinse solution including deionized water, an organic solvent, and/or dried (e.g., spin-dry, N₂, vapor-dry etc.).

The cleaning composition described herein may be advantageously used for post etch or post ash residue removal (PERR, PARR), post CMP cleaning, surface preparation, and pre-metal plating cleaning, particularly of a substrate comprising both a cobalt or cobalt alloy surface and a copper or copper alloy surface.

The cleaning composition described herein may be advantageously used in a process for the manufacture of a semiconductor device, comprising the step of
(a) providing a microelectronic substrate that comprises (i) a cobalt or cobalt alloy surface and
   (ii) a copper or copper alloy surface having post etch residues, post ash residues, or chemical mechanical planarization (CMP) residues thereon;
(b) providing a composition according to anyone of claims 1 to 10;
(c) contacting (i) the cobalt or cobalt alloy surface and (ii) the copper or copper alloy surface with the composition for a time and at a temperature effective to at least partly remove the post etch residues, post ash residues, or chemical mechanical planarization (CMP) residues from the substrate.

Preferably the post etch residues, post ash residues, or chemical mechanical planarization (CMP) residues are completely removed from the substrate.

The following examples shall further illustrate the present invention without restricting the scope of this invention.

### EXAMPLES

The etch rate experiments were carried out as follows:

Two cobalt and two copper blank wafer coupons (each 2×2 cm) were pre-etched in 1 wt. % oxalic acid for 1 min each. The coupons were rinsed with water dried in air. The thickness of the cobalt and copper levels on the coupons were determined by XRF.

The ready-to-use PCC formulation was heated up to 60° C. and two cobalt blank wafer coupons (2×2 cm) were dipped into the tempered solution for 3 min. The coupons were then rinsed with ultra-pure water and dried in air. The same procedure was repeated with two copper blank wafer coupons. The thickness of the wafer coupons was determined by XRF. The static etch rates were determined by calculating the difference in cobalt/copper level thickness before and after PCC solution treatment divided by the etching time of 3 min.

The following materials were used in electronic grade purity. All amounts given for the compounds in the compositions are absolute amounts, i.e. excluding any water, in the overall mixture.

Cobalt corrosion inhibitors:
A-1 Dodecylbenzenesulfonic acid
A-2 Phosphoric acid, mono- and di- C₆-C₁₀-alkyl esters
A-3 ([Iminobis(methylene)]bisphosphonic acid, N-coco-alkyl derivatives) ammonium salt
A-4 N-Cocoyl sarcosine (mixture of C to C₁₈ alkyl sarcosines)
A-5 N-Oleyl sarcosine (C₁₇ alkyl sacosine)
A-6 Octadecylphosphonic acid (insoluble, comparative)
A-7 N-Lauroyl sarcosine (C₁₁ alkyl sarcosine) (comparative)
A-8 Ethoxylated C₁₀ guerbet alcohol R¹R²—C—CH₂O(CH₂—CH₂O)ₙR³H (n=8) (comparative)
A-9 Alkylpolyglycoside (comparative)
A-10 4-butyl-benzoyl-sarcosine (comparative)
A-11 Lauric acid (comparative)
   Copper corrosion inhibitors:
B-1 Benzotriazole (BTA)
B-2 5-Chlorobenzotriazole (5-CI BTA)
B-3 4,5,6,7-Tetrahydro-1 H-Benzotriazole
B-4 1,2,3 Triazole (comparative)
B-5 5-phenyl-tetrazole (comparative)
B-6 Imidazole (comparative)
B-7 Benzimidazole (comparative)
B-8 Uric acid (comparative)
B-9 Isophthalic acid (comparative)
   C₂ to C₇ monoamino alkanols:
C-1 2-amino-2-methyl-propan-1-ol
C-2 Triethanolamine
C-3 Diisopropanolamine
C-4 N-Methyl-diethanol amine
C-5 N-Methyl-2-aminoethan-1-ol
C-6 1-Amino-propan-2-ol (Alaninol) DL
C-7 2-Amino-propan-1-ol (racemate)
C-8 4-amino-butan-1-ol
C-9 3-Amino-propan-1-ol
C-10 2-[2-(Dimethylamino)ethoxy]ethanol
C-11 3-Amino-propane-1,2-diol
C-12 2-(2-Aminoethoxy)ethanol (Diglycolamine)
   Other N-containing species
C-13 Ammonia (comparative)
C-14 2-(2-Aminoethylamino)ethanol (comparative)
C-15 3-Amino-octan-4-ol (H₉C₄—C(OH)—C(NH₂)—C₂H₅) (comparative)
   Further additives:
D-1 Maleic acid acrylic acid co-polymer
D-2 Citric acid
D-3 DMSO
D-4 Ascorbic acid

### Example 1

Several corrosion inhibitor combinations were tested. Aqueous compositions comprising 10 wt % C-1, 0.63 wt % D-1, 0.50 wt % D-2, 15 wt % D-3, 3.50% D-4, and the inhibitors listed in table 1, rest water, were prepared. The concentrate was stirred for additional 30 min at r.t. The concentrate was 50 times diluted to obtain the ready-to-use PCC formulation.

Two cobalt and two copper blank wafer coupons (each 2×2 cm) were pre-etched in 1 wt. % oxalic acid for 1 min each. The coupons were rinsed with water dried in air. The thickness of the cobalt and copper levels on the coupons were determined by XRF. The ready-to-use PCC formulation was heated up to 60° C. and two cobalt blank wafer coupons (2×2 cm) were dipped into the tempered solution for 3 min. The coupons were then rinsed with ultra-pure water and dried in air. The same procedure was repeated with two copper blank wafer coupons. The thickness of the wafer coupons was determined by XRF. The static etch rates (SER) were determined by calculating the difference in cobalt/copper level thickness before and after PCC solution treatment divided by the etching time of 3 min.

TABLE 1

| Co inhibitor | | Cu inhibitor | | | |
|---|---|---|---|---|---|
| | Conc. | | Conc. | Co SER | Cu SER |
| Compound | [wt %] | Compound | [wt %] | [A/min] | [A/min] |
| A-1 | 1.00 | B-1 | 0.50 | 0.44 | 0.23 |
| A-2 | 1.00 | B-1 | 0.50 | 0.11 | 0.43 |
| A-3 | 1.00 | B-1 | 0.50 | 0.33 | 0.36 |
| A-4 | 1.00 | B-1 | 0.50 | 0.03 | 0.52 |
| A-5 | 1.00 | B-1 | 0.50 | 0.72 | 0.22 |
| A-5 | 1.00 | B-2 | 0.50 | 0.97 | 0.49 |
| A-5 | 1.00 | B-3 | 0.50 | 0.70 | 2.00 |
| A-1 | 0.75 | B-2 | 0.10 | 0.32 | 0.17 |
| A-4 | 1.00 | B-2 | 0.10 | 0.68 | 0.08 |
| A-5 | 1.00 | B-2 | 0.10 | 0.10 | 0.34 |

Table 1 shows that all combinations of cobalt and copper etching inhibitors show low static etch rates on cobalt and copper.

### Example 2

Several monoamino alkanols C-1 to E-12 were tested. Compositions comprising 1.00 wt % A-4 0.50 wt % B-1, 0.63 wt % C-1, 0.50 wt % C-2, 15 wt % D-3, 3.50% D-4, and the monoamino alkanols listed in table 2, rest water, were prepared. The compositions were diluted 1:50 (wt) with water before use. Etching tests were performed with the compositions as described in example 1. The results are depicted in table 2.

In comparison, ammonia (0-13) and amines (G-14, 015) were tested under the same conditions. The results are depicted in table 2.

TABLE 2

| Monoamino alkanol | | | | |
|---|---|---|---|---|
| | Conc. | Co SER | Cu SER | |
| Compound | [wt %] | [A/min] | [A/min] | Comment |
| C-1 | 10.0% | 0.03 | 0.52 | Good surface quality post etch |
| C-2 | 16.7% | 0.57 | 0.25 | Good surface quality post etch |
| C-3 | 14.9% | 0.74 | 0.65 | Good surface quality post etch |
| C-4 | 13.4% | 0.67 | 0.72 | Good surface quality post etch |
| C-5 | 8.4% | 0.14 | 0.5 | Good surface quality post etch |
| C-6 | 8.4% | 0.91 | 0.81 | Good surface quality post etch |
| C-7 | 8.4% | 0.38 | 0.61 | Good surface quality post etch |
| C-8 | 10.0% | 0.33 | 0.83 | Good surface quality post etch |
| C-9 | 8.4% | 0.35 | 0.33 | Good surface quality post etch |
| C-10 | 14.9% | 0.06 | 0.59 | Good surface quality post etch |
| C-11 | 10.2% | 0.50 | 0.02 | Good surface quality post etch |
| C-12 | 11.8% | 0.92 | 0.17 | Good surface quality post etch |
| C-13 | 3.9% | 0.75 | 0.74 | Pitting during Cu-PCC with a |
| | | | | formulation comprising |
| | | | | ammonia |
| C-14 | 11.7% | 3.96 | 1.4 | Good surface quality post etch |
| | | | | but high Co SER |
| C-15 | 16.4% | | | Turbidity (forms emulsion) |

Table 2 shows that mono-amino-alcohols (number of C<8) give a clear solution, low SER and good surface quality post etch.

### Example 3

The synergistic effect of the cobalt and copper corrosion inhibitors A and B was determined by measuring the SER for both inhibitors for both metals Co and Cu. The results are shown in Tables 3 and 4, respectively. The relative remaining Co and Cu etch rates were determined by dividing the etch rate with the inhibitor by the etch rate without any additive.

TABLE 3

| Inhibitor | | | | remaining | remaining |
|---|---|---|---|---|---|
| | Conc. | Co SER | Cu SER | Co SER | Cu SER |
| Compound | [wt %] | [A/min] | [A/min] | [%] | [%] |
| none | 0 | 17 | 5 | 100 | 100 |
| A-1 | 1.00 | 1.9 | 3.5 | 11.18 | 70.0 |
| A-2 | 1.00 | 2.7 | 4.8 | 15.88 | 96.0 |
| A-3 | 1.00 | 0.4 | 7.1 | 2.35 | 142.0 |
| A-5 | 1.00 | 2.4 | 4.6 | 14.12 | 92.0 |
| A-7 | 1.00 | 12.2 | 6.2 | 71.76 | 124.0 |
| A-4 | 1.00 | 1.1 | 3.9 | 6.47 | 78.0 |

Inhibitors A1, A2, A3, A4 and A5 show good inhibition properties for cobalt (Co).

TABLE 4

| Inhibitor | | | | remaining | remaining |
|---|---|---|---|---|---|
| | Conc. | Co SER | Cu SER | Co SER | Cu SER |
| Compound | [wt %] | [A/min] | [A/min] | [%] | [%] |
| | | 17 | 5 | 100 | 100 |
| B-1 | 0.5 | 13 | 0.88 | 76.47 | 17.6 |
| B-2 | 0.5 | 17.76 | 0.53 | 104.47 | 10.6 |
| B-3 | 0.5 | 9.67 | 0 | 56.88 | 0 |
| B-4 (comp.) | 0.5 | 7.5 | 1.8 | 44.12 | 36.0 |

Inhibitors B1, B2, and B3 according to the invention show good inhibition properties for Copper (Cu). B4 also shows an inhibiting effect but less good than B1, B2, and B3.

The expected values (calc.) were calculated by multiplying the respective remaining SER [%] of each single component from table 3 and 4 with the respective base line value for the etching rate without inhibitors (17 A/mmn for Co and 5 A/mmn for Cu). The results are depicted in table 5.

TABLE 5

| | | | | | | Co SER | Cu SER |
|---|---|---|---|---|---|---|---|
| Co inhibitor | | Cu inhibitor | | Co SER | Cu SER | [A/min] | [A/min] |
| | Conc. | | Conc. | [A/min] | [A/min] | Exp. | Exp. |
| Compound | [wt %] | Compound | [wt %] | Calc. | Calc. | 17 | 5 |
| A-1 | 1.00 | B-1 | 0.50 | 1.45 | 0.62 | 0.44 | 0.23 |
| A-2 | 1.00 | B-1 | 0.50 | 2.06 | 0.84 | 0.11 | 0.43 |
| A-3 | 1.00 | B-1 | 0.50 | 0.31 | 1.25 | 0.33 | 0.36 |
| A-4 | 1.00 | B-1 | 0.50 | 0.84 | 0.69 | 0.03 | 0.52 |
| A-5 | 1.00 | B-1 | 0.50 | 1.84 | 0.81 | 0.72 | 0.22 |
| A-5 | 1.00 | B-2 | 0.50 | 2.51 | 0.49 | 0.97 | 0.49 |
| A-5 | 1.00 | B-3 | 0.50 | 1.37 | 0.0 | 0.70 | 2.00 |

A synergistic effect is present if one of the measured Co or the Cu etch rate is lower than the expected (calculated) value. For the combination of A1 or A2 with B1 the experimental SER for cobalt is lower than expected. For the combination of A3 with B1 the experimental SER for copper is lower than expected. For the combination of A4 and AS with B1 the experimental SER for cobalt and copper is lower than expected. For the combination of AS with B2 and B3 the experimental SER for cobalt is lower than expected.

1. An alkaline composition for cleaning a substrate comprising a structure of copper or copper alloy and a structure comprising cobalt or cobalt alloy, the composition comprising:
(a) 0.0001 to 0.2% by weight of a cobalt corrosion inhibitor selected from the group consisting of
(i) a C₁₀ to C₂₀ alkyl sulfonic acid or a C₁₂ to C₂₄ alkylbenzene sulfonic acid,
(ii) a C₈ to C₁₇ alkyl phosphonic acid or an amino phosphonic acid of formula I1 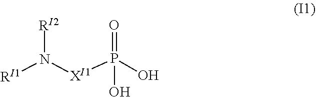
wherein
R^{I1} is C₈ to C₂₀ alkyl,
R^{I2} is selected from the group consisting of H, C₁ to C₆ alkyl, and —X^{I1}—P(O)(OH)₂, and
X^{I1} is selected from the group consisting of C₁ to C₆ alkanediyl,
(iii) a C₁₂ to C₁₈ alkyl carboxylic acid, a sarcosine of formula I2, or cocoyl sarcosine 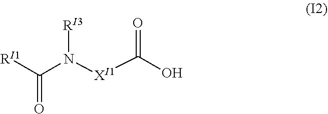
wherein
R^{I1} is C₁₂ to C₂₀ alkyl,
R^{I3} is selected from the group consisting of H, C₁ to C₆ alkyl, and —X^{I1}—C(O)—OH, and
X^{I1} is selected from the group consisting of C₁ to C₆ alkanediyl,
(iv) a C₁₀ to C₂₀ mono or dialkylester of phosphoric acid,
which alkyl groups (i) to (iv) may be interrupted by one or more O or may comprise one or more double bonds, and
(v) a salt of (i) to (iv);
(b) 0.0001 to 0.5% by weight of a copper corrosion inhibitor selected from the group consisting of benzotriazole, 5-chloro benzotriazole, 4-methyl benzotriazole; 5-methyl benzotriazole; tetrahydro benzotriazole; and methyl-benzotriazole-1-yl)-methyl-imino-bis-ethanol;
(c) 0.05 to 1% by weight of a C₂ to C₇ monoamino alkanol; and
(d) a solvent;
wherein the solvent consists essentially of water.

2. The composition according to claim 1, wherein the cobalt inhibitor is selected from the group consisting of dodecyl benzyl sulfonic acid, cocoyl sarcosine, oleyl sarcosine, cocoyl-phosphonic acid derivative, and a C₆-C₁₀ alkanol phosphoric acid ester.

3. The composition according to claim 1, wherein the copper inhibitor is selected from the group consisting of benzotriazole, 5-chloro benzotriazole, 4-methyl benzotriazole; 5-methyl benzotriazole; tetra-hydro benzotriazole; and methyl-benzotriazole-1-yl)-methyl-imino-bis-ethanol.

4. The composition according to claim 1, wherein the monoamino alkanol is selected from the group consisting of 2-amino-ethan-1-ol, 2-amino-propan-1-ol, 3-amino-propan-1-ol, 1-amino-propan-2-ol, 2-amino-1-methyl-propan-1-ol, 3-amino-1-methyl-propan-1-ol, 2-amino-2-methyl-propan-1-ol; 2-amino-butan-1-ol, 3-amino-butan-1-ol, 4-amino-butan-1-ol, 2-amino-3-methyl-butan-1-ol, 4-amino-2-methyl-butan-1-ol, 3-amino-1-methyl-butan-1-ol, 2-amino-1-methyl propanol, 3,3′-iminobis(N,N-dimethylpropylamine), triethanolamine, Diisopropanolamine, N-Methyl-diethanolamine, 2-[2-(Dimethylamino)ethoxy]ethanol, 3-Amino-1,2-propanediol, and 2-(2-Aminoethoxy)ethanol (Diglycolamine).

5. The composition according to claim 1, further comprising a dispersing agent selected from the group consisting of a acrylic acid-maleic acid copolymer and a polyvinylpyrrolidone, a copolymer of styrol and acrylic acid, benzene sulfonic acid-formaldehyde condensate, naphthaline sulfonic acid formaldehyde condensate.

6. The composition according to claim 1, further comprising a complexing agent selected from the group consisting of C₂ to C₆ hydroxycarboxylic acids.

7. The composition according to claim 6, wherein the complexing agent is citric acid.

8. The composition according to claim 1, further comprising a reducing agent selected from the group consisting of sugar alcohols.

9. The composition according to claim 1, further comprising an oxygen scavenger selected from the group consisting of ascorbic acid, 4-methoxyphenol, and gallic acid.

10. The composition according to claim 1, further comprising a water-miscible aprotic or protic organic solvent in an amount of 0.1 to 1% by weight.

11. The composition according to claim 1, having a pH of 9 to 11.5.

12. A concentrate for preparing a composition according to claim 1, the concentrate comprising:
(a) 0.01 to 5% by weight of the cobalt corrosion inhibitor;
(b) 0.01 to 1% by weight of the copper corrosion inhibitor;
(c) 1 to 20% by weight of the monoamino alkanol;
(d) 0 to 20% by weight of one or more organic solvents; and
(e) rest water.

13. A method of using the composition according to claim 1, the method comprising using the composition for removing
(a) post etch residue (PERR) or post ash residue (PARR), or
(b) chemical mechanical planarization (CMP) residues,
from a substrate comprising (i) a cobalt or cobalt alloy surface and (ii) a copper or copper alloy surface.

14. A process of processing a microelectronic device, the process comprising:
(a) providing a microelectronic substrate that comprises (i) a cobalt or cobalt alloy surface and (ii) a copper or copper alloy surface having post etch residues or post ash residues thereon;
(b) providing the composition according to claim 1; and
(c) contacting (i) the cobalt or cobalt alloy surface and (ii) the copper or copper alloy surface with the composition for a time and at a temperature effective to at least partly, remove the post etch residues or post ash residues from the substrate.

15. A process of processing a microelectronic device, the process comprising:
(a) providing a microelectronic substrate that comprises (i) a cobalt or cobalt alloy surface and (ii) a copper or copper alloy surface having chemical mechanical planarization (CMP) residues thereon;
(b) providing the composition according to claim 1; and
(c) contacting (i) the cobalt or cobalt alloy surface and (ii) the copper or copper alloy surface with the composition for a time and at a temperature effective to at least partly remove the chemical mechanical planarization (CMP) residues from the substrate.

16. A process for manufacturing of a semiconductor device, comprising the processing according to claim 14.

17. The composition according to claim 1, wherein the complexing agent selected from the group consisting of C₂ to C₆ hydroxycarboxylic acids is in an amount of 0.005 to 0.5% by weight.

18. The composition according to claim 1, wherein the reducing agent is sorbitol.

19. The composition according to claim 1, wherein the reducing agent is in an amount of 0.03 to 1.5% by weight.

20. The process according to claim 15, comprising (c) contacting (i) the cobalt or cobalt alloy surface and (ii) the copper or copper alloy surface with the composition for a time and at a temperature effective to completely remove the chemical mechanical planarization (CMP) residues from the substrate.
